(19) United States
(12) Patent Application Publication
(10) Pub. No.: US 2015/0287824 A1
(43) Pub. Date: Oct. 8, 2015

(54) INTEGRATED CIRCUITS WITH STRESSED SEMICONDUCTOR SUBSTRATES AND PROCESSES FOR PREPARING INTEGRATED CIRCUITS INCLUDING THE STRESSED SEMICONDUCTOR SUBSTRATES

(71) Applicant: GLOBALFOUNDRIES, Inc., Grand Cayman (KY)

(72) Inventors: Shishir Ray, Clifton Park, NY (US); Jin Ping Liu, Hopewell Junction, NY (US); Bharat Krishnan, Clifton Park, NY (US)

(73) Assignee: GLOBALFOUNDRIES, Inc., Grand Cayman (KY)

(21) Appl. No.: 14/244,322

(22) Filed: Apr. 3, 2014

(51) Int. Cl. H01L 29/78; H01L 29/66; H01L 29/161; H01L 21/268; H01L 21/265; H01L 29/167

(52) U.S. Cl. CPC H01L 29/7842; H01L 21/26513; H01L 29/167; H01L 29/161; H01L 21/268; H01L 29/66477

(57) ABSTRACT

Integrated circuits with stressed semiconductor substrates, processes for preparing stressed semiconductor substrates, and processes for preparing integrated circuits including stressed semiconductor substrates are provided herein. An exemplary process for preparing a stressed semiconductor substrate includes providing a semiconductor substrate of a semiconductor material having a first crystalline lattice constant; introducing a dopant on and into a surface layer of the semiconductor substrate via ion implantation at an amount above a solubility limit of the dopant in the semiconductor material to form a dopant-containing surface layer of the semiconductor substrate; applying energy to the dopant-containing surface layer of the semiconductor substrate with an ultra-short pulse laser to form a molten semiconductor:dopant layer on a surface of the semiconductor substrate; and removing the energy such that the molten semiconductor:dopant layer forms a solid semiconductor:dopant layer with a second crystalline lattice having a second lattice constant that differs from the first lattice constant.

### TECHNICAL FIELD

The technical field generally relates to integrated circuits and processes for preparing integrated circuits. More particularly, the technical field relates to integrated circuits with stressed semiconductor substrates, processes for preparing stressed semiconductor substrates, and processes for preparing integrated circuits including stressed semiconductor substrates.

### BACKGROUND

Metal oxide semiconductor (MOS) transistors find wide-ranging use in electronic devices, such as microprocessors, microcontrollers, and application-specific integrated circuits. MOS transistors generally include a gate electrode formed above a semiconductor substrate, with the gate electrode being insulated from the semiconductor substrate by a thin layer of gate insulator material. A source and a drain are spaced apart regions of either N-type or P-type semiconductor material and are generally embedded within the semiconductor substrate adjacent to the gate electrode on either side thereof A region in the semiconductor substrate between the source and the drain, and beneath the gate electrode, forms a channel of the MOS transistor.

It is known that the mobility of charge carriers, i.e., electrons and holes, in the channel can be increased when the semiconductor substrate is stressed in the channel. Depending upon the type of transistor, different types of stress have different effects on carrier mobility. For example, the mobility of electrons in the channel of an NMOS transistor can be increased by applying a tensile stress to the channel in the semiconductor substrate, whereas the mobility of holes in the channel of a PMOS transistor can be increased by applying compressive stress to the channel in the semiconductor substrate.

Stress can be introduced into semiconductor substrates using a global approach, in which biaxial stress is introduced across a surface of the semiconductor substrate along two axes, or a local approach, in which uniaxial stress is introduced into the semiconductor substrate at discreet locations in the semiconductor substrate along a single axis. To introduce stress into semiconductor substrates using the global approach, exemplary structures including silicon germanium (SiGe) stress-relaxed buffer layers or silicon carbide (SiC) stress-relaxed buffer layers can be formed on the surface of the semiconductor substrate. To introduce stress into semiconductor substrates using the local approach, stress is introduced only to local areas adjacent to the channel of the transistor from a local structure such as, for example, a stress liner, embedded silicon SiGe source/drain structures, embedded SiC source/drain structures, and stress-generating shallow trench isolation structures. Due to easier integration within device formation processes, local approaches to introduction of stress into semiconductor substrates have generally been favored, although global approaches to introduction of stress generally enable stronger and more uniform stress to be introduced than local approaches. However, as integrated circuit structures continue to get smaller and thinner (e.g., FinFET structures), higher levels of tensile and compressive stress are desired than are achieved via conventional techniques.

Accordingly, it is desirable to provide novel processes for preparing semiconductor substrates with higher levels of tensile or compressive stress. It is also desirable to provide processes for preparing devices including a stressed semiconductor substrate in which stress is introduced therein through the novel process. Furthermore, other desirable features and characteristics of the present invention will become apparent from the subsequent detailed description of the invention and the appended claims, taken in conjunction with the accompanying drawings and this background of the invention.

### BRIEF SUMMARY

Processes for preparing stressed semiconductor substrates, processes for preparing integrated circuits including stressed semiconductor substrates, and integrated circuits with stressed semiconductor substrates are provided herein. In one embodiment, a process for preparing a stressed semiconductor substrate includes: providing a semiconductor substrate of a semiconductor material having a first crystalline lattice with a first lattice constant; introducing a dopant on and into a surface layer of the semiconductor substrate via ion implantation at an amount above a solubility limit of the dopant in the semiconductor material to form a dopant-containing surface layer of the semiconductor substrate; applying energy to the dopant-containing surface layer of the semiconductor substrate with an ultra-short pulse laser to form a molten semiconductor:dopant layer on a surface of the semiconductor substrate; and removing the energy such that the molten semiconductor:dopant layer forms a solid semiconductor:dopant layer with a second crystalline lattice having a second lattice constant that differs from the first lattice constant, thereby forming a stressed semiconductor substrate.

In another embodiment, a process for preparing an integrated circuit including a stressed semiconductor substrate includes: providing a semiconductor substrate of a semiconductor material having a first crystalline lattice with a first lattice constant; introducing a dopant on and into a surface layer of the semiconductor substrate via ion implantation at an amount above a solubility limit of the dopant in the semiconductor material to form a dopant-containing surface layer of the semiconductor substrate; applying energy to the dopant-containing surface layer of the semiconductor substrate with an ultra-short pulse laser to form a molten semiconductor:dopant layer on a surface of the semiconductor substrate; removing the energy such that the molten semiconductor:dopant layer forms a solid semiconductor:dopant layer with a second crystalline lattice having a second lattice constant that differs from the first lattice constant, thereby forming a stressed semiconductor substrate; and forming a transistor in and on the stressed semiconductor substrate.

In another embodiment, an integrated circuit includes a stressed semiconductor substrate and a transistor disposed in and on the stressed semiconductor substrate. In this embodiment, the stressed semiconductor substrate includes a semiconductor material having a crystalline lattice with a first lattice constant; and a semiconductor:dopant layer having a thickness of less than about 5 nm disposed on the semiconductor material. The semiconductor:dopant layer has a crystalline lattice having a second lattice constant that differs from the first lattice constant.

### BRIEF DESCRIPTION OF THE DRAWINGS

The present invention will hereinafter be described in conjunction with the following drawing figures, wherein like numerals denote like elements, and wherein:

FIG. 1 is an illustration of ion implantation of dopant atoms into and on a surface layer of a semiconductor substrate according to an exemplary embodiment;

FIG. 2 is an illustration of melting dopant atoms and a surface layer of a semiconductor substrate with an ultra-fast pulse laser according to an exemplary embodiment;

FIG. 3 is an illustration of a stressed semiconductor substrate with a semiconductor:dopant layer disposed on a semiconductor substrate prepared according to an exemplary embodiment;

FIG. 4 is a schematic cross-sectional side view of a device including a stressed semiconductor substrate prepared in accordance with another exemplary embodiment.

### DETAILED DESCRIPTION

The following detailed description is merely exemplary in nature and is not intended to limit the invention or the application and uses of the invention. Furthermore, there is no intention to be bound by any theory presented in the preceding background or the following

### DETAILED DESCRIPTION

Integrated circuits with stressed semiconductor substrates, processes for preparing a stressed semiconductor substrate, and processes for preparing integrated circuits including stressed semiconductor substrates are provided herein. The processes for preparing the stressed semiconductor substrate enable tensile or compressive stress to be introduced into the semiconductor substrate through a multistep implant and anneal scheme. Processes described herein utilize conventional ion implantation techniques to introduce an amorphous layer of a suitable dopant into and on a surface layer of a semiconductor substrate at an amount above the solubility limit of the dopant within the semiconductor material. An ultra-short laser pulse (i.e., nanosecond scale) is then used to melt the deposited dopant and a thin layer of the semiconductor material. The laser energy is sufficiently high to melt the deposited dopant and a thin layer of semiconductor material, yet the pulse is short enough so that the thin molten semiconductor:dopant layer quickly cools and re-crystallizes into a more periodic structure than is typically achieved via implantation alone. Specifically, the melt/re-crystallization techniques described herein lead to higher dopant occupation of substitutional sites in the recrystallized semiconductor:dopant layer. In some embodiments, the recrystallized semiconductor:dopant layer is less than about 5 nanometers thick, such as less than about 2 nm thick, such as less than about 1 nm thick. Because of the dopant occupation of substitutional sites in the recrystallized semiconductor:dopant layer, the recrystallized semiconductor:dopant layer has a different crystallization lattice constant than the underlying semiconductor substrate, resulting in stress.

Stressed semiconductor substrates prepared according to processes described herein can easily be integrated into existing processes for preparing electronic devices that include stressed semiconductor substrates, such as devices that include transistors formed on semiconductor substrates. In any event, the preparation of a stressed semiconductor:dopant layer on the surface of a semiconductor substrate via implantation of a dopant followed by ultra-short pulse laser-based melting and fast annealing represents a novel approach for introducing tensile stress into semiconductor substrates.

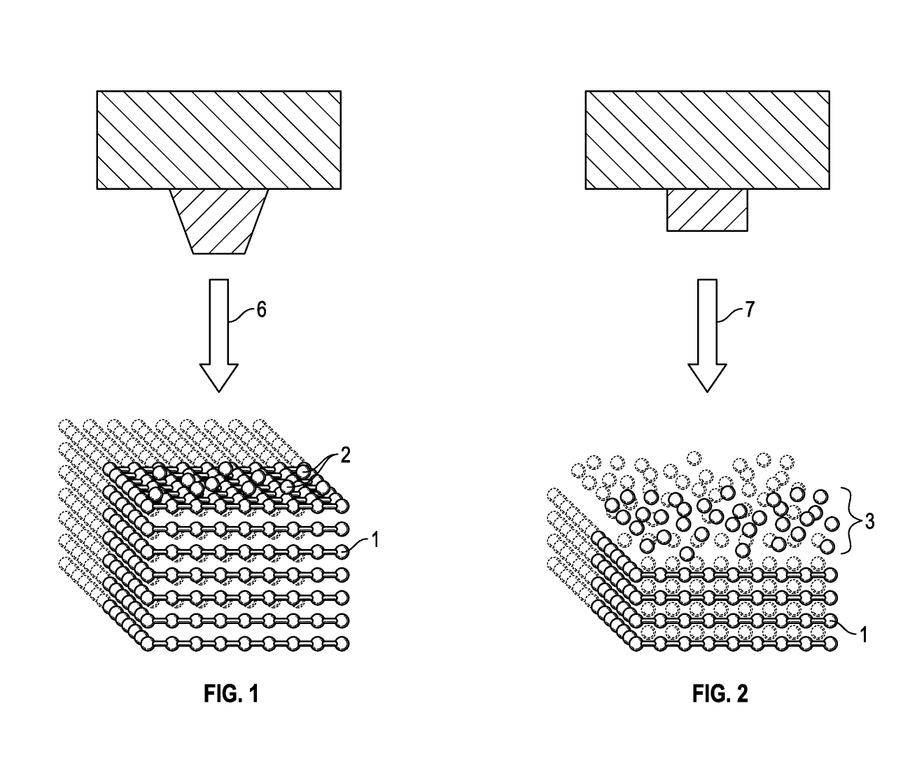

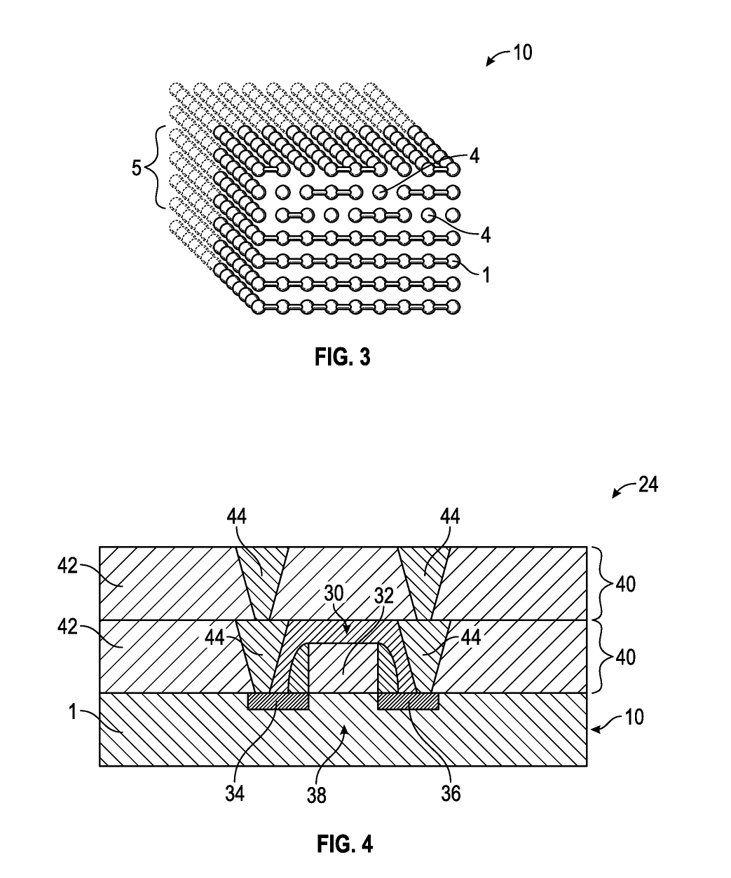

An exemplary embodiment of a process for preparing a stressed semiconductor substrate 10 will now be addressed with reference to FIGS. 1-3. In some embodiments, the stressed semiconductor substrate 10 is prepared having tensile stress therein, which is preferred when an NMOS transistor is to be included on the stressed semiconductor substrate 10 due to increased mobility of electrons through the tensile stressed semiconductor substrate 10. It should be understood that the identity of the dopant and semiconductor substrate material determines whether the resulting stressed semiconductor substrate exhibits tensile or compressive stress. In embodiments where tensile stress is desired, a dopant is selected for a particular semiconductor substrate material such that the semiconductor:dopant layer has a crystalline lattice with a lattice constant that is less than the crystalline lattice constant of the semiconductor substrate material. In alternative embodiments where compressive stress is desired, a dopant is selected for a particular semiconductor substrate material such that the semiconductor:dopant layer has a crystalline lattice with a lattice constant that is greater than the crystalline lattice constant of the semiconductor substrate material.

Referring to FIG. 1, a semiconductor substrate 1 of a first material having a first crystalline lattice constant is provided, and the semiconductor substrate 1 generally has a lattice structure that naturally forms based on the first crystalline lattice constant to generate minimal stress in the semiconductor substrate 1. The first material may be any semiconductor material that is known for industrial use in electronic devices. Examples of the first material include, but are not limited to, those chosen from silicon, silicon germanium (SiGe), germanium (Ge), gallium arsenide (GaAs), or indium phosphide (InP). For example, in an embodiment, when the first material is silicon, the silicon is present in an amount of from about 95 to about 100 mol %, such as from about 99 to about 100 mol %, based upon the total amount of atoms in the semiconductor substrate 1. The silicon may be substantially pure, i.e., dopants and/or impurities are present in amounts of less than or equal to 1 mol % based upon the total amount of atoms in the semiconductor substrate 1 and are desirably absent from the semiconductor substrate 1.

Thickness of the semiconductor substrate 1 may vary depending on source materials and desired products to be manufactured. In an embodiment, the semiconductor substrate 1 is further defined as silicon-on-insulator (SOI) substrate and has a thickness of from about 50 to about 1500 nm, such as from about 50 to about 300 nm. In another embodiment, the semiconductor substrate 1 is further defined as a bulk silicon substrate and has a thickness of up to 1 mm, such as from about 500 to about 750 nm. Thicknesses of the semiconductor substrate 1 within the above ranges are sufficiently thin to enable stress to be introduced therein while remaining sufficiently thick to minimize the incidence of cracking or breakage.

In the exemplary process, a suitable dopant 2 is introduced into an upper surface layer of the semiconductor substrate 1 via ion implantation 6 such that the dopant 2 is deposited at or above the solubility limit of the dopant 2 in the semiconductor substrate. Suitable dopants may vary depending on the composition of the semiconductor substrate and the desired type and degree of stress. In some embodiments, dopants may be selected from the group consisting of boron (B), carbon (C), phosphorous (P), and nitrogen (N). However, as will be appreciated by one of skill in the art, the processes described herein are not limited to these particular dopants.

Any implantation technique suitable for a dopant and semiconductor substrate of interest may be used. In some embodiments, a dopant is deposited via ion implantation 6. In such embodiments, the energy of the dopant ions, as well as the dopant ion species and the composition of the target determine the depth of penetration of the dopant ions in the substrate. In some embodiments, ion implantation energies are in the range of about 1 to about 500 K eV, such as a range of about 1 to about 10 K eV, with specific energies selected for a particular dopant ion, particular semiconductor substrate, and desired penetration depth. For example, in a specific exemplary embodiment, boron may be introduced as a dopant into a surface layer of a silicon substrate via ion implantation at an energy of about 4.4 K eV.

Referring again to FIGS. 1-3, after the dopant 2 has been deposited into and on a surface layer of the semiconductor substrate 1, the surface of the substrate 1 containing the dopant 2 is then irradiated with an ultra-short laser pulse 7 with sufficient energy to melt at least a monolayer of the semiconductor substrate 1. In some embodiments, at least a portion of the ultra-short laser pulse 7 may also melt at least a portion of the dopant material 2. Any suitable laser capable of ultra-short pulse operation and sufficient power may be used. In some embodiments, the laser has appropriately short pulse length and appropriately high power to melt the semiconductor substrate 1 to a depth of about 5 nm or less, such as about 2 nm or less, such as about 1 nm or less. Melting such a thin layer on the surface of the semiconductor substrate 1 in this way allows for formation of a thin molten semiconductor:dopant layer 3 on the surface of the semiconductor substrate 1 that has dopant atoms 2 homogenously distributed throughout the molten layer 3. Such a thin homogenous molten layer 3 cools and recrystallizes very quickly resulting in stress within the solid semiconductor:dopant layer 5. Limiting the melt depth helps reduce potential damage to the rest of the substrate 1 from the anneal process and reduces the time necessary for the molten layer 3 to cool and recrystallize into the semiconductor:dopant layer 5. Without wishing to be bound by theory, it is believed that fast cooling and recrystallization of molten layer 3 results in a semiconductor:dopant layer 5 with a more periodic structure than the pre-melt dopant implanted surface, with the dopant atoms 2 being incorporated into substitutional sites 4 homogeneously distributed throughout the recrystallized semiconductor:dopant layer 5. The incorporation of the dopant atoms 2 into substitutional sites 4 in the recrystallized semiconductor:dopant layer 5 results in the recrystallized semiconductor:dopant layer 5 having a crystalline lattice constant that differs from the crystalline lattice constant of the semiconductor substrate 1, causing stress. The resulting stressed semiconductor substrate 10 may then be used to prepare any semiconductor device where a stressed semiconductor may be desired.

In some embodiments, an ultra-short pulse laser with nanosecond scale pulse time and about 1 to about 2 J/cm² fluence (i.e., energy density) is used to achieve the above described surface melt. For example, in some embodiments, the ultra-short pulse time is about 10 ns to about 200 ns, such as about 100 ns to about 200 ns, such as about 140 ns. In some embodiments, the laser fluence is about 1 J/cm² to about 2 J/cm², such as about 1.4 J/cm² to about 1.5 J/cm², such as about 1.45 J/cm².

In some embodiments, the processes described herein may be used to prepare stressed semiconductor materials with stress levels that are much higher than previously obtainable. For instance, stressed semiconductor materials may be prepared with up to about 5% dopant substitution. In some embodiments, stressed semiconductor materials may be prepared with about 3% to about 5% dopant substitution, such as between about 3% and 4% dopant substitution. In one exemplary embodiment, a boron doped silicon film may be prepared on a silicon substrate with about 4% dopant substitution, resulting in tensile stress equivalent to about 40% SiGe stress.

An exemplary embodiment of a process for preparing a portion of an integrated circuit 24 including a stressed semiconductor substrate 10 will now be addressed, as shown in FIG. 4. In this embodiment, the stressed semiconductor substrate 10 may be prepared as described above, with the semiconductor substrate 1 and the stressed semiconductor:dopant layer 5 formed thereon as described above. A transistor 30, such as a metal oxide semiconductor (MOS) transistor 30, is formed on the stressed semiconductor substrate 10 contacting the stressed semiconductor:dopant layer 5. The transistor 30 may be formed on the stressed semiconductor substrate 10 in accordance with conventional designs and includes a gate electrode 32 that is disposed on the stressed semiconductor substrate 10. A source 34 and a drain 36 are embedded within the stressed semiconductor substrate 10 adjacent to the gate electrode 32 on either side thereof. A region in the semiconductor substrate 1 between the source 34 and the drain 36, and beneath the gate electrode 32, forms a channel 38 of the transistor 30. Although not shown in FIG. 4, it is to be appreciated that millions of transistors may be formed on the stressed semiconductor substrate 10. Depending upon whether the transistor 30 is a PMOS transistor or NMOS transistor, the stress generated in the stressed semiconductor substrate may appropriately be compressive stress or tensile stress to promote carrier mobility in the channel 38 of the MOS transistor 30. In accordance with the embodiment shown in FIG. 4, at least one level of interconnect routing 40 is formed over the transistor 30 on the semiconductor substrate 1, which is consistent with integrated circuit manufacture. FIG. 4 shows two levels of interconnect routing 40, which generally include a layer of interlayer dielectric material 42 with embedded electrical interconnects 44 disposed therein that can be designed to form complex electrical circuitry that is characteristic of integrated circuits.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A process for preparing a stressed semiconductor substrate, said process comprising:
providing a semiconductor substrate of a semiconductor material having a first crystalline lattice with a first lattice constant;
introducing a dopant on and into a surface layer of the semiconductor substrate via ion implantation at an amount above a solubility limit of the dopant in the semiconductor material to form a dopant-containing surface layer of the semiconductor substrate;
applying energy to the dopant-containing surface layer of the semiconductor substrate with an ultra-short pulse laser to form a molten semiconductor:dopant layer on a surface of the semiconductor substrate; and
removing the energy such that the molten semiconductor:dopant layer forms a solid semiconductor:dopant layer with a second crystalline lattice having a second lattice constant that differs from the first lattice constant, thereby forming a stressed semiconductor substrate.

2. The process of claim 1, wherein the ultra-short pulse laser has a pulse time of about 10 ns to 200 ns, and a fluence of about 1 J/cm² to 2 J/cm².

3. The process of claim 1, wherein the semiconductor material comprises a semiconductor material selected from the group consisting of silicon, silicon germanium (SiGe), germanium (Ge), gallium arsenide (GaAs), and indium phosphide (InP).

4. The process of claim 1, wherein the dopant is selected from the group consisting of boron (B), carbon (C), phosphorous (P), and nitrogen (N).

5. The process of claim 1, wherein the solid semiconductor:dopant layer comprises about 3% to about 5% dopant substitution within the solid semiconductor:dopant layer crystalline lattice.

6. The process of claim 1, wherein the second lattice constant is less than the first lattice constant.

7. The process of claim 1, wherein the second lattice constant is greater than the first lattice constant.

8. The process of claim 1, wherein the dopant is introduced on and into the surface layer of the semiconductor substrate via ion implantation at an energy of about 1 to about 10 K eV.

9. The process of claim 1, wherein the semiconductor substrate comprises silicon and the dopant is boron.

10. A process for preparing an integrated circuit including a stressed semiconductor substrate, said process comprising:
providing a semiconductor substrate of a semiconductor material having a first crystalline lattice with a first lattice constant;
introducing a dopant on and into a surface layer of the semiconductor substrate via ion implantation at an amount above a solubility limit of the dopant in the semiconductor material to form a dopant-containing surface layer of the semiconductor substrate;
applying energy to the dopant-containing surface layer of the semiconductor substrate with an ultra-short pulse laser to form a molten semiconductor:dopant layer on a surface of the semiconductor substrate;
removing the energy such that the molten semiconductor:dopant layer forms a solid semiconductor:dopant layer with a second crystalline lattice having a second lattice constant that differs from the first lattice constant, thereby forming a stressed semiconductor substrate; and
forming a transistor in and on the stressed semiconductor substrate.

11. The process of claim 10, wherein the ultra-short pulse laser has a pulse time of about 10 ns to 200 ns, and a fluence of about 1 J/cm² to 2 J/cm².

12. The process of claim 10, further comprising forming at least one level of interconnect routing over the transistor on the stressed semiconductor substrate.

13. The process of claim 10, wherein the semiconductor substrate comprises a semiconductor material selected from the group consisting of silicon, silicon germanium (SiGe), germanium (Ge), gallium arsenide (GaAs), and indium phosphide (InP).

14. The process of claim 10, wherein the dopant is selected from the group consisting of boron (B), carbon (C), phosphorous (P), and nitrogen (N).

15. The process of claim 10, wherein the solid semiconductor:dopant layer comprises about 3% to about 5% dopant substitution within the solid semiconductor:dopant layer crystalline lattice.

16. The process of claim 10, wherein the second lattice constant is less than the first lattice constant.

17. The process of claim 10, wherein the second lattice constant is greater than the first lattice constant.

18. The process of claim 10, wherein the dopant is introduced on and into the surface layer of the semiconductor substrate via ion implantation at an energy of about 1 to about 10 K eV.

19. The process of claim 10, wherein the semiconductor material is silicon and the dopant is boron.

20. An integrated circuit comprising:
a stressed semiconductor substrate comprising:
a semiconductor material having a first crystalline lattice with a first lattice constant; and
a semiconductor:dopant layer disposed on the semiconductor material, wherein the semiconductor:dopant layer has a second crystalline lattice having a second lattice constant that differs from the first lattice constant, wherein the semiconductor:dopant layer has a thickness of less than about 5 nm; and
a transistor disposed in and on the semiconductor substrate.
